(19) United States
(12) Patent Application Publication
(10) Pub. No.: US 2008/0258238 A1
(43) Pub. Date: Oct. 23, 2008

(54) Semiconductor Device Manufactured Using an Oxygenated Passivation Process During High Density Plasma Deposition

(75) Inventor: Duncan M. Rogers, Plano, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/738,552

(22) Filed: Apr. 23, 2007

(51) Int. Cl. H01L 29/78; H01L 21/762

(52) U.S. Cl. 257/397; 438/424; 257/E29.255; 257/E21.628

(57) ABSTRACT

In one aspect, the method comprises forming trenches in a semiconductor substrate and filling the trenches with a dielectric material. The process of filling the trenches includes depositing the dielectric material with a plasma gas mixture, etching the dielectric material with a chemical etch including nitrogen fluoride and using a passivation process to passivate the dielectric material after etching with a gas mixture that includes oxygen and hydrogen.

### TECHNICAL FIELD

The invention is directed, in general, to a semiconductor device and manufacture of that device, and more specifically, directed to using an oxygenated passivation process during a high density plasma deposition to manufacture that device.

### BACKGROUND

As semiconductor devices have continued to shrink well into the sub-micron range, semiconductor device manufacturers strive to address problems associated with this continued miniaturization and to insure that the quality of the devices is maintained. One of the many areas of interest is void formation within isolation trenches. Voids are highly undesirable because they can be a source of defectivities and, in the case of a trench isolation structure, they may also cause ineffective electrical isolation.

To address this problem, manufacturers have developed a sputter deposition/etch routine that uses hydrogen or helium as the etching component to fill isolation trenches. This sputter deposition/etch process fills the isolation trench in a semi-layering fashion, which helps to reduce void formation within the trench. The layers that result from the sputter deposition/etch process reduce pinch-offs and voids. However, the sputter deposition/etch process requires a longer processing time to fill the trenches in this manner.

To improve throughput and decrease production time, semiconductor manufacturers have turned to a sputter/chemical etch process that involves the use of nitrogen trifluoride NF₃ as the etching component. While this sputter/chemical etch process decreases fabrication time, the NF₃ produces fluorine atoms that can diffuse into the surrounding silicon substrate and eventually into the gate oxide. Though the mechanism is not fully understood, fluoride contamination causes defectivities within the semiconductor device.

Accordingly, what is needed in the art is a process for reducing fluoride contamination associated with the above-discussed conventional processes.

### SUMMARY

In one embodiment, the method comprises placing a hardmask over a semiconductor substrate and patterning the hardmask to form openings therein. An etch is conducted through the openings to form trenches in the semiconductor substrate. The trenches are filled with a dielectric material that includes depositing the dielectric material with a plasma gas mixture including silane, hydrogen, and oxygen, etching the dielectric material with a chemical etch including a gas mixture of nitrogen trifluoride, hydrogen, and helium. The dielectric material is passivated, after etching, with a gas mixture that includes oxygen and hydrogen, wherein a flow rate of the oxygen ranges from about 135 sccm to about 285 sccm and a flow rate of hydrogen ranges from about 375 sccm to about 1700 sccm and at a low frequency power ranging from about 5000 watts to about 6500 watts and a high frequency power ranging from about 750 watts to about 1300 watts, the passivating reducing fluorine contaminants in the dielectric material.

In another embodiment, there is provided a method of manufacturing a semiconductor device that comprises forming trenches in a semiconductor substrate and filling the trenches with a dielectric material. The process of filing the trenches includes depositing the dielectric material with a plasma gas mixture, etching the dielectric material with a chemical etch including nitrogen fluoride and passivating the dielectric material after etching with a gas mixture that includes oxygen and hydrogen.

In yet another embodiment, there is provided a semiconductor device. In this embodiment, the device includes isolation trenches located within a semiconductor wafer substrate. The isolation trenches are filled with a dielectric material formed using a chemical etch including nitrogen trifluoride and a plasma deposition process, wherein the semiconductor substrate has a center to edge average fluorine concentration that is less than about 2.10E19 atoms/cm³ at a depth within the semiconductor substrate of about less than 5 microns. Transistors are located over and within the semiconductor substrate. Each of the transistors is isolated from each other by the isolation trenches. The transistors include a gate oxide located over the semiconductor substrate, a gate electrode located over the gate oxide, and source/drains located within the semiconductor substrate and adjacent the gate electrodes. Dielectric layers are located over the transistors and interconnects are located over and within the dielectric layers that connect the transistors to other devices.

### BRIEF DESCRIPTION OF THE DRAWINGS

For a better understanding, reference is now made to the following descriptions taken in conjunction with the accompanying drawings, in which:

FIGS. 1-4B illustrate various stages of the formation of isolation trenches, including the passivation processes;

FIGS. 5-6 illustrate plots of data that shown how the passivation of various embodiments of the invention reduce fluorine contamination when compared to conventional processes; and

FIG. 7 illustrates an IC that can be manufactured using the invention.

### DETAILED DESCRIPTION

The embodiments of the invention, as discussed below, recognizes the benefits associated with passivating a dielectric material formed using a fluoride-containing chemistry, with a gas mixture containing oxygen. It has been found that using oxygen to passivate the dielectric materials reduces the fluoride contamination that occurs during a deposition/etch process used to form the dielectric material in isolation trenches. The reduction in the fluoride contamination is a beneficial improvement over conventional processes because less fluorine is available to diffuse from the isolation trenches and to other portions of the device where it can cause defectivities.

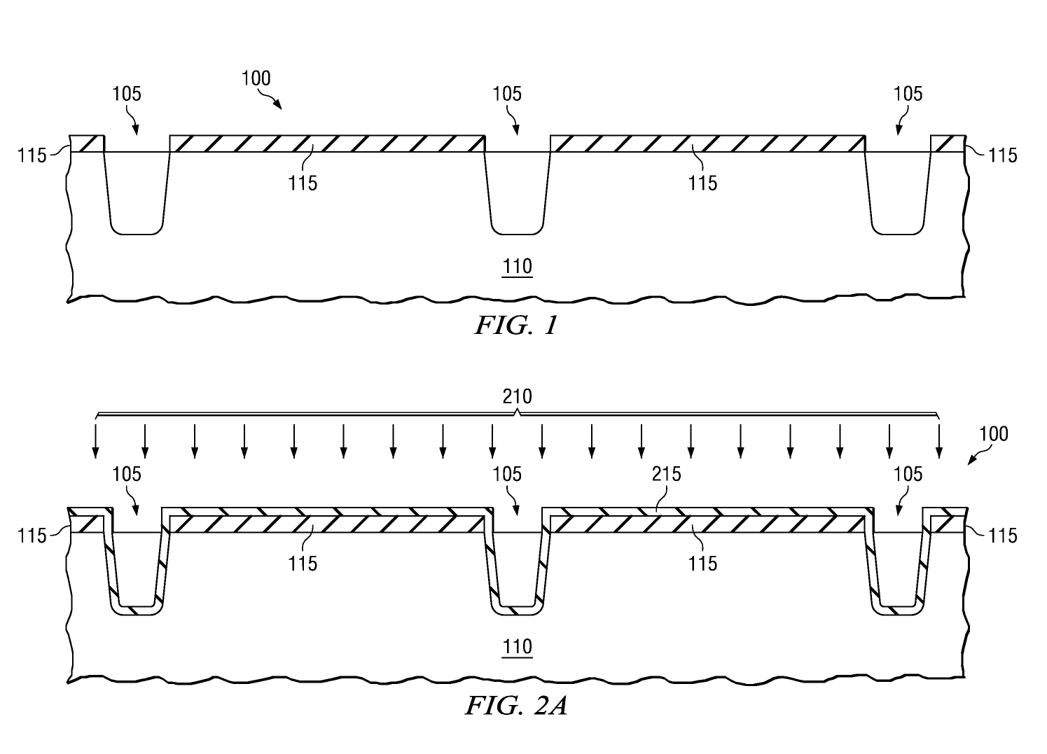

FIG. 1 illustrates a semiconductor device 100 after the formation of isolation trenches 105 formed in semiconductor substrate 110. It should be generally noted that, unless otherwise stated, conventional processes and materials may be used to construct the various components discussed herein. The substrate 110 may be any layer located over a semiconductor wafer or may be a region formed in or from the substrate 110 itself, such as an appropriately doped active region. The substrate 110 may be any semiconductor substrate known to those skilled in the art, such as silicon, silicon germanium, gallium arsenide, etc. A hardmask 115, e.g., silicon nitride, is deposited over the substrate 110 and patterned and etched to form openings in the hardmask 115. In many cases, the hardmask 115 will be deposited over a pad oxide layer, which is not shown in this particular embodiment. An etch is conducted through the openings in the hardmask 115 to form the trenches 105. Following the formation of the trenches 105, an oxide liner, which is not shown, may be deposited in the trenches 105 prior to filling them with a dielectric material.

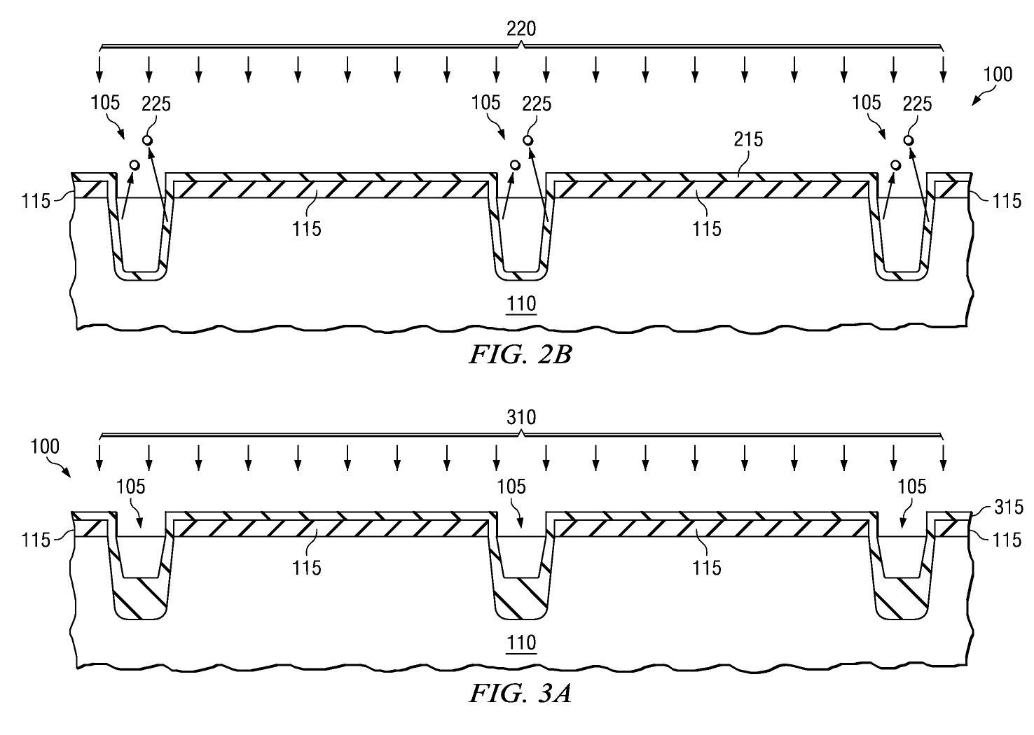

FIG. 2A shows the device 100 undergoing a deposition/etch process 210, e.g., a plasma or sputter deposition/etch, to deposit a dielectric material 215, e.g., a high density plasma (HDP) silicon oxide material. As well known, a plasma or sputter deposition/etch involves both a deposition component and an etching component. In applications where a net deposition process is desired, the process parameters will be adjusted to achieve a net deposition of the desired material.

For example, in one embodiment, silane, hydrogen, and oxygen may be used to form the dielectric material 215. In one aspect, the silane may be flowed at a rate of about 80 sccm, the hydrogen may be flowed at a rate of about 375 sccm, and the oxygen may be flowed at a rate of about 135 sccm. This gas mixture may also contain helium having a flow rate of 300 sccm as an etch component. Additionally, a high frequency power (HFP) of the deposition/etch may range from about 750 watts to about 1300 watts and the low frequency power (LFP) may range from about 6100 watts to about 6200 watts. These parameters are given as examples, and it should be understood that the process parameters may vary, depending on the deposition tool and device design.

Conventional processes may also be used to conduct the etch portion of the deposition/etch process 210. For example, in one embodiment, the etch component may comprise nitrogen fluoride, such as nitrogen trifluoride, hydrogen and helium. In one aspect of this embodiment, the nitrogen fluoride may be flowed at a rate of about 300 sccm, the hydrogen may be flowed at a rate of about 700 sccm, and the helium may be flowed at a rate of about 100 scc. Additionally, the high frequency power of the etching may be about 1800, and the LFP may be about 5000. These deposition parameters are also given as examples and may vary depending on the deposition tool and the device design.

The amount of time that the deposition/etch process 210 is conducted may vary and will depend on processing conditions and the type of tool being used. In one embodiment, the deposition/etch process 210 is cycled; that is, it is conducted for a period of time and then paused such that no significant material is deposited. In most embodiments, the pause will include discontinuing the deposition process (both gas flows and power) before resuming the deposition process. After the deposition/etch process 210 is discontinued the device 100 is subjected to a passivation process 220 as shown in FIG. 2B, which removes fluoride contamination 225. The various embodiments of the passivation process 220 are discussed below.

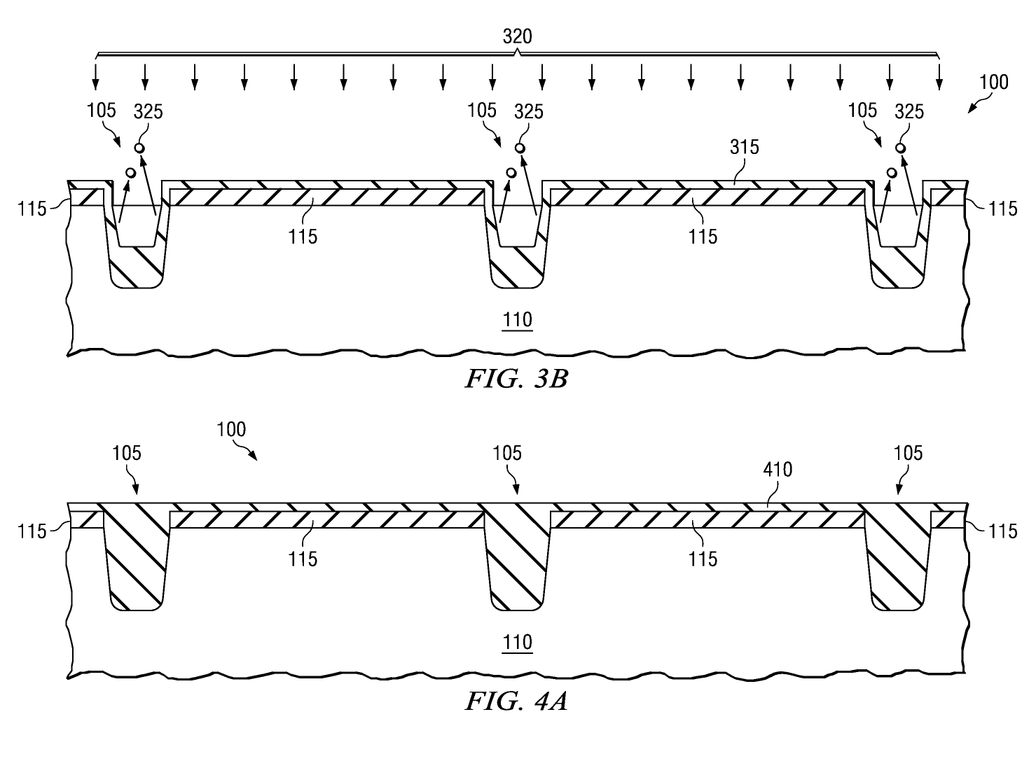

Following the passivation process 220, the deposition/etch process is resumed, designated as deposition/etch process 310 in FIG. 3A. The same parameters as used to conduct deposition/etch 220 may also be used to conduct process 310. As seen here, additional dielectric material 315 is added to the trenches 105. Process 310 is conducted for a period of time, that may vary as mentioned above regarding process 210 and then discontinued.

After the deposition/etch process 310 is discontinued the device 100 is subjected to a passivation process 320 as shown in FIG. 3B, which removes fluoride contamination 325 that occurred with the deposition/etch process 310. Passivation process 320 may be the same as passivation process 220.

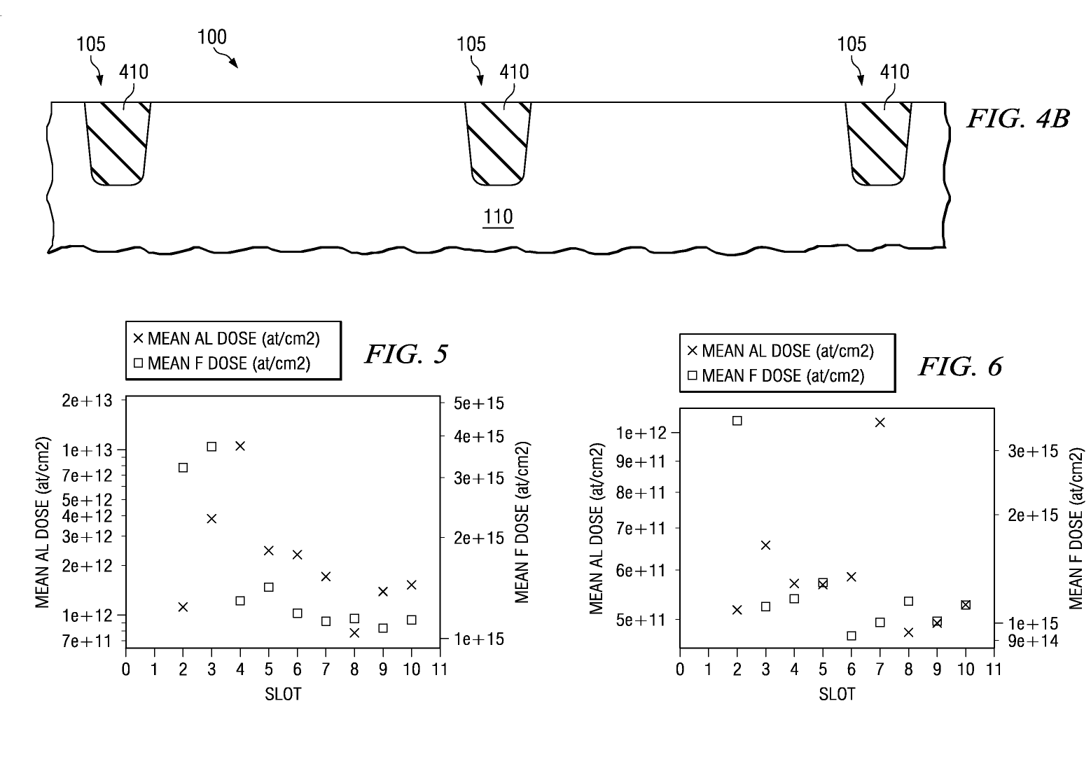

Deposition/etch processes 210, 310 and passivation process 220, 320 are repeated in the manner described above until the trenches 105 are completely filled with dielectric material 410 as seen in FIG. 4A. Conventional processes may then be used to remove the excess dielectric material 410, the hardmask 115, and any underlying layers, such as a pad oxide, from the substrate 110 to arrive at the structure shown in FIG. 4B. Conventional processes may then be used to complete the device 100 in the manner described below.

Embodiments of passivation processes 220 and 320 and the reduction in fluorine contaminants associated with those embodiments will now be discussed. It should be understood that the following embodiments may be combined with the various embodiments of the above-discussed deposition/etch processes in any number of ways.

Passivation parameters were varied over 19 different slots (sample wafers), the results of which are set forth in Tables 1 and 2 below and which correspond to FIGS. 5 and 6, respectively.

TABLE I

| | | LF | H₂ Flow | He Flow | O₂ Flow | HF | |
|---|---|---|---|---|---|---|---|
| | | Power | Rate | Rate | Rate | Power | Time |
| Slot | H Pass | (W) | (sccm) | (sccm) | (sccm) | (W) | (s) |
| 2 | N | | | | | | |
| 3 | Y | 6150 | 1500 | 0 | 0 | 1000 | 10 |
| 4 | Y | 6150 | 375 | 0 | 135 | 1300 | 10 |
| 5 | Y | 6150 | 375 | 0 | 135 | 1000 | 10 |
| 6 | Y | 6150 | 675 | 0 | 135 | 1300 | 10 |
| 7 | Y | 6150 | 975 | 0 | 135 | 1300 | 10 |
| 8 | Y | 6150 | 1500 | 0 | 135 | 1300 | 10 |
| 9 | Y | 6150 | 675 | 0 | 285 | 1300 | 10 |
| 10 | Y | 6150 | 675 | 0 | 285 | 1000 | 10 |

TABLE I presents passivation parameters for 9 different sample wafers. Except for sample 2, in which no passivation was conducted, the LFP (bias on the plasma) was kept constant across all of the samples at about 6150 watts, and the HFP (bias on the wafer) ranged from about 1000 watts to about 1300 watts. Though the LFP was kept constant in the samples, in other embodiments, the LFP may range from about 5000 watts to about 6500 watts, and in another aspect, the LFP may range from about 6100 watts to about 6200 watts. The flow rate of hydrogen varied from about 375 sccm to about 1500 sccm, and the flow rate of oxygen ranged from about 0.0 sccm to about 285 sccm. The beneficial reduction in fluorine contamination for these samples is shown in FIG. 5. As seen in FIG. 5, in samples 2 and 3 where either no passivation was conducted or only hydrogen was used to passivate the device, as is conventionally done, the fluorine contamination was not reduced and ranged above 3E15 atoms/cm². However, in those embodiments that incorporated oxygen into the passivation step, fluorine contamination was significantly reduced and ranged well below 2E15 atoms/cm², with sample 8 showing the lowest combined fluorine and aluminum contamination and sample 9 showing the most reduction in fluorine contamination. FIG. 5 also illustrates that reduction in fluorine contamination occurred without generally increasing the amount of aluminum contamination.

TABLE II

| | | LF | H₂ Flow | He Flow | O₂ Flow | HF | |
|---|---|---|---|---|---|---|---|
| | | Power | Rate | Rate | Rate | Power | Time |
| Slot | H Pass | (W) | (sccm) | (sccm) | (sccm) | (W) | (s) |
| 1 | N | | | | | | |
| 2 | N | | | | | | |
| 3 | Y | 6150 | 1500 | 0 | 135 | 1300 | 10 |
| 4 | Y | 6150 | 1500 | 0 | 135 | 1000 | 10 |
| 5 | Y | 6150 | 1500 | 0 | 135 | 750 | 10 |
| 6 | Y | 6150 | 1500 | 0 | 285 | 1300 | 10 |
| 7 | Y | 6150 | 1500 | 0 | 285 | 1000 | 10 |
| 8 | Y | 6150 | 1500 | 0 | 285 | 750 | 10 |
| 9 | Y | 6150 | 1700 | 0 | 285 | 1000 | 10 |
| 10 | Y | 6150 | 1700 | 0 | 285 | 750 | 10 |

TABLE II presents passivation parameters for 10 additional, different wafers. Except for samples 1 and 2, in which no passivation was conducted, the LFP (bias on the plasma) was kept constant across all of the samples at about 6150 watts, and the HFP (bias on the wafer) ranged from about 750 watts to about 1300 watts. Though the LFP was kept constant in the samples, in other embodiments, the LFP may range from about 5000 watts to about 6500 watts, and in another aspect may range from about 6100 watts to about 6200 watts. The flow rate of hydrogen varied from about 1500 sccm to about 1700 sccm, and the flow rate of oxygen ranged from about 135 sccm to about 285 sccm. The reduction in fluorine contamination for these samples is shown in FIG. 6. As seen in FIG. 6, in sample 2 where no passivation was conducted, the fluorine contamination was not reduced and ranged above 3E15 atoms/cm². However, in those embodiments that incorporated oxygen into the passivation step, fluorine contamination was significantly reduced and ranged well below 2E15 atoms/cm², with sample 6 showing the most reduction in fluorine contamination and sample 9 showing the lowest combined fluorine and aluminum concentrations. FIG. 6 also illustrates that reduction in fluorine contamination occurred without generally increasing the amount of aluminum contamination.

From the foregoing it is readily seen that the passivation process provided by the various embodiments set forth above beneficially reduced the amount of fluorine contamination present in the device when compared to conventional processes that either use only hydrogen to passivate or do not passivate during the trench filling process.

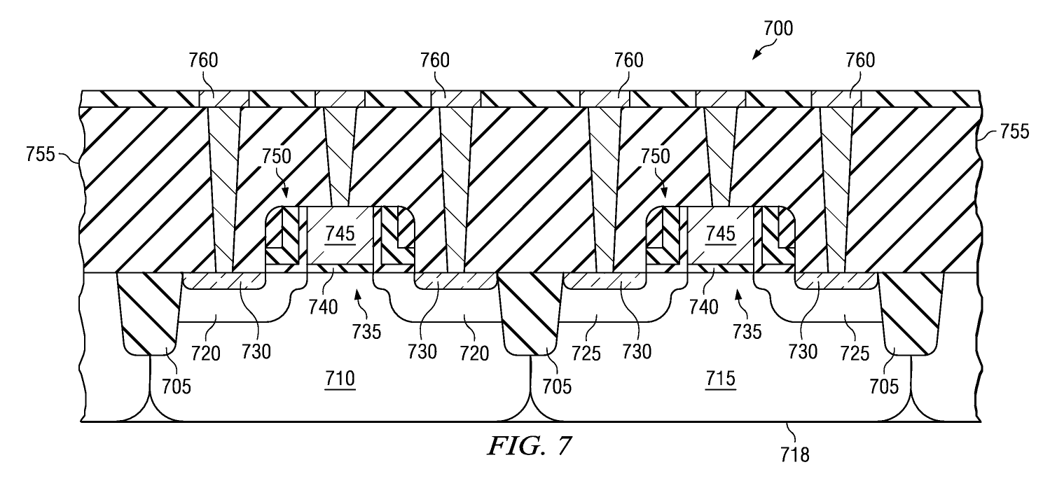

Following the formation and passivation of the isolation trenches 105, conventional processes may be used to complete the semiconductor device 700 as shown in FIG. 7. In one embodiment, the device 700 is configured as an integrated circuit (IC), which may be a complementary device, e.g. a CMOS device. In the illustrated embodiment, the device 700 includes the isolation trenches 705 formed by the embodiments discussed above. The isolation trenches 705 are located in doped wells 710 and 715 that may be conventionally formed and located in an epitaxial layer or a doped region of a semiconductor substrate 718, e.g., a wafer. The illustrated embodiment further includes source/drains 720, 725 that may also be conventionally formed and appropriately doped with a dopant opposite to that used to dope wells 710 and 715. The source/drains 720, 725 may be conventionally silicided with a metal to form silicide contacts 730 that improve electrical contact. Gate structures 735 are located adjacent the source/drains 720, 725 and may include conventional components, such as a gate oxide 740, a gate electrode 745 and sidewall spacers 750, which may comprise a stacked structure as shown. The wells 710, 715, source/drains 720, 725, contacts 370 and gate structures 735 form a transistor. A dielectric material 755 is formed over the gate structures 735 and have interconnects 760, which connect the gate structures 735 and source/drains to other conventional components, not shown. The interconnects 755 may be damascene structures, as shown, dual damascene structures, or some other conventionally formed interconnect design. Those skilled in the art would understand how to complete the device 700 and form an IC.

In one embodiment, of the semiconductor device 700, the semiconductor substrate 718 has a center to edge average fluorine concentration that is less than about 2.10E19 atoms/cm³ at a depth within the semiconductor substrate 718 of about less than 5 microns. In another embodiment, the substrate 718 has a fluorine dose concentration that ranges from about 1E19 atoms/cm² at a depth of about 0.0 microns to about 5E19 atoms/cm² at a depth of about 0.5 microns.

Those skilled in the art will appreciate that other and further additions, deletions, substitutions and modifications may be made to the described embodiments without departing from the scope of the invention.

What is claimed is:

1. A method of manufacturing a semiconductor device, comprising:
placing a hardmask over a semiconductor substrate;
patterning the hardmask to form openings therein;
etching through the openings to form trenches in the semiconductor substrate; and
filling the trenches with a dielectric material, including:
depositing the dielectric material with a plasma gas mixture including silane, hydrogen, and oxygen;
etching the dielectric material with a chemical etch including a gas mixture of nitrogen trifluoride, hydrogen, and helium; and
passivating the dielectric material, after etching, with a gas mixture that includes oxygen and hydrogen, wherein a flow rate of the oxygen ranges from about 135 sccm to about 285 sccm and a flow rate of hydrogen ranges from about 375 sccm to about 1700 sccm and at a low frequency power ranging from about 5000 watts to about 6500 watts and a high frequency power ranging from about 750 watts to about 1300 watts, the passivating reducing fluorine contaminants in the dielectric material.

2. The method recited in claim 1, wherein the high frequency power is about 750 watts and the low frequency power is about 6150 watts.

3. The method recited in claim 2, wherein passivating includes flowing hydrogen at a rate ranging from about 675 sccm to about 1700 sccm.

4. The method recited in claim 3, wherein the flow rate of oxygen is about 285 sccm.

5. The method recited in claim 1, wherein a high frequency power of the etching is about 1800 watts and a low frequency power of the etching is about 5000 watts.

6. The method recited in claim 5, wherein a flow rate of the nitrogen trifluoride is about 300 sccm, a flow rate of the hydrogen is about 700 sccm, and a flow rate of the helium is about 100 sccm.

7. The method recited in claim 1, wherein a high frequency power of the depositing ranges from about 1200 watts to about 1300 watts and a low frequency power ranges from about 6100 watts to about 6200 watts.

8. The method recited in claim 7, wherein a flow rate of silane is about 80 scam, a flow rate of hydrogen is about 375 scam, and a flow rate of oxygen is about 135 sccm.

9. The method recited in claim 1, wherein the semiconductor device is an integrated circuit and the method further includes:
forming a transistor over and within the semiconductor substrate and between the filled trenches;
forming dielectric layers over the transistors; and
forming interconnects over and within the dielectric layers to interconnect the transistors to other devices.

10. A method of manufacturing a semiconductor device, comprising:
forming trenches in a semiconductor substrate; and
filling the trenches with a dielectric material, including:
depositing the dielectric material with a plasma gas mixture;
etching the dielectric material with a chemical etch including nitrogen fluoride; and
passivating the dielectric material after etching with a gas mixture that includes oxygen and hydrogen.

11. The method recited in claim 10, wherein passivating includes using a high frequency power ranging from about 750 watts to about 1300 watts and a low frequency power ranging from about 6100 watts to about 6200 watts.

12. The method recited in claim 11, wherein passivating includes flowing oxygen at a rate that ranges from about 135 sccm to about 285 sccm and flowing hydrogen at a rate that ranges from about 375 sccm to about 1700 sccm.

13. The method recited in claim 11, wherein a high frequency power of the etching ranges from about 750 watts to about 1300 watts and a low frequency power ranges from about 6100 watts to about 6200 watts.

14. The method recited in claim 13, wherein the nitrogen fluoride is nitrogen trifluoride and the chemical etch further includes hydrogen and helium, and wherein a flow rate of the nitrogen trifluoride is about 300 sccm, a flow rate of the hydrogen is about 700 sccm and a flow rate of the helium is about 100 sccm.

15. The method recited in claim 11, wherein a high frequency power of the depositing ranges from about 1200 watts to about 1300 watts and a low frequency power ranges from about 6100 watts to about 6200 watts.

16. The method recited in claim 15, wherein the plasma gas mixture includes silane, hydrogen and oxygen, and a flow rate of silane is about 80 sccm, a flow rate of hydrogen is about 375 sccm, and a flow rate of oxygen is about 135 sccm.

17. The method recited in claim 11, wherein the semiconductor device is an integrated circuit and the method further includes:
forming a transistor over and within the semiconductor substrate and between the filled trenches;
forming dielectric layers over the transistors; and
forming interconnects over and within the dielectric layers to interconnect the transistors to other devices.

18. The method recited in claim 11, wherein passivating includes removing fluorine or aluminum contaminants from the semiconductor substrate.

19. A semiconductor device, comprising:
isolation trenches located within a semiconductor wafer substrate filled with a dielectric material formed using a chemical etch including nitrogen trifluoride and a plasma deposition process, wherein the semiconductor substrate has a center to edge average fluorine concentration that is less than about 2.10E19 atoms/cm³ at a depth within the semiconductor substrate of about less than 5 microns;
transistors located over and within the semiconductor substrate, each of the transistors isolated from each other by the isolation trenches and including a gate oxide located over the semiconductor substrate, a gate electrode located over the gate oxide, and source/drains located within the semiconductor substrate and adjacent the gate electrodes;
dielectric layers located over the transistors;
interconnects located over and within the dielectric layers that connect the transistors to other devices.

20. The device recited in claim 19, wherein the fluorine concentration ranges from about 1E19 atoms/cm³ to 5E19 atoms/cm³ in the depth of about 0.0 microns to about 0.5 microns.
